(19) United States
(12) Patent Application Publication
(10) Pub. No.: US 2006/0265789 A1
(43) Pub. Date: Nov. 23, 2006

(54) Nanotube with a T shaped structure and a field effect transistor, and a method of manufacturing the same

(75) Inventors: Takazumi Kawai, Tokyo (JP); Yoshiyuki Miyamoto, Tokyo (JP)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(73) Assignee: NEC Corporation

(21) Appl. No.: 11/355,135

(22) Filed: Feb. 16, 2006

(30) Foreign Application Priority Data
Feb. 16, 2005 (JP) 2005-038910

(51) Int. Cl. H01L 29/00

(52) U.S. Cl. 977/742

(57) ABSTRACT

To realize a transistor with a channel and a gate, both being formed with nanotubes, by joining the nanotubes in the form of SP3 bonding, a substrate, on which a pair of source and drain electrodes 27, and a gate terminal 28 are formed, is prepared (Fig. (a)), and then a catalytic layer 20 is formed at the one of the source and drain electrodes 27 (Fig. (b)). A first CNT 23 is formed (Fig. (d)) between the pair of source and drain electrodes 27 by growing the CNT (Fig. (c)) in which the catalytic layer 20 is a core. A second CNT 24 is picked by a holding means 25, and after a cap is eliminated and an opening portion is cleaned using the electron beam as needed, the opening portion is contacted to the side of the first CNT 23, thereby joining the two CNT (fig. (e)). The other end portion of the second CNT 24 is positioned at the gate terminal 28 (Fig. (f)). End portions of the CNT are fixed on the electrodes and the terminal by selectively irradiating metallic ion.

### FIELD OF THE INVENTION

The present invention relates to a nanotube with a T shaped structure and a field effect transistor, and a method of manufacturing them, more specifically to the T letter shaped structure in which two nanotubes are jointed with the SP³ bonding and the field effect transistor using the same, and the method of manufacturing them.

### BACKGROUND OF THE INVENTION

The nanotube is a cylindrical body with the diameter of 0.4 nm to several tens of nm which has a structure with a sheet of six-membered ring structure like graphite to be rolled in a thecal shape. Because of a unique electric property that behaves like semiconductor or metal based on the diameter or the helical state, that is, the degree of angles between a direction of the axis of a nanotube and a direction of carbon atom arrangement, the nanotube has drawn attention as a raw material capable of bringing a variety of functional elements such as the transistor into reality, and then research and development thereof have been actively conducted.

The conventional typical example of the transistor using a carbon nanotube has a structure in which one end of the carbon nanotube is connected to the source electrode, the other end of it being connected to the drain electrode, and the carbon nanotube is connected to the gate electrode made of a metallic film arranged there through an insulating film (for example, refer to patent literature 1).

On the other hand, it is known as the prior art structure in which two carbon nanotubes are joined, that two carbon nanotubes are joined in the shapes of “X”, “Y” or “T” (for example, refer to non patent literature 1).

The combination of two carbon nanotubes in the shape of “X” can be made in a way that two carbon nanotubes are superimposed in the shape of a cross, then, the electron beam is irradiated to the overlapping portion and annealing is implemented thereto. In the process, specifically, two carbon nanotubes are joined by the way that carbon atoms are sputtered by the irradiation of the electron beam and then activated carbon in the vacancy formed by sputtering joins with carbon in the other nanotube. Further, the combination of two carbon nanotubes in the shapes of “Y” or “T” is formed by eliminating one branch of the combination of carbon nanotubes in the shape of “X” using the electron beam irradiation.

Those combinations of carbon nanotubes have a structure in which the hollow portions of the two tubes are continuous, and the two carbon nanotubes are joined in the form of SP² bonding.
(Patent Literature 1) Japanese laid open patent publication 2003-017508.
(Non Patent Literature 1) M. Terrones, et al., “Molecular Junctions by Joining Single-Walled Carbon Nanotubes”, PHYSICAL REVIEW LETTERS, Vol. 89, No. 7, 075505 (12 Aug. 2002)

### DISCLOSURE OF THE INVENTION

### PROBLEM TO BE SOLVED BY THE INVENTION

It is respected that a very microscopic transistor can be formed using a nanotube because the nanotube itself has a fine structure. In the conventional nanotube transistor, however, because the nanotube transistor is connected to the gate electrode made of a metallic film arranged there through an insulating film, the length of channels under the gate electrode is determined with the dimension of the metallic electrode. Further, because it is necessary to use the photo lithography method for forming the gate electrode, there is a limit to the miniaturization.

Also, in the conventional nanotube transistor, because the nanotube constituting the channel is limited to ones having semiconductor property, there is low freedom in selection of material.

On the other hand, because the conventional combination of two nanotubes has the structure in which the two carbon nanotubes are joined in the form of SP² bonding, there exists an electrically conductive state between the two nanotubes.

In case that the two nanotubes are in the conductive state electrically, the applicable scope must be limited, taking into account of application of the nanotube combination to electronic devices such as transistors.

The subject of the present invention is to solve problems in the conventional technologies mentioned above. Accordingly, the first object of the present invention is to provide a structure in which two nanotubes are joined in the non conductive state electrically, thereby widening the scope applicable to electronic devices of the nanotube.

The second object of the present invention is to provide a fully miniaturized transistor using the nanotube with such a structure.

### MEANS FOR SOLVING THE PROBLEM

According to the present invention, in order to achieve the above objects there is provided a nanotube with a T shaped structure wherein a side of a first nanotube and an end of an opening portion of a second nanotube are arranged in the form of SP³ bonding.

According to the present invention, in order to achieve the above objects there is provided a nanotube with a T shaped structure in which an end of an opening portion of a second nanotube joins with a side of a first nanotube wherein the first nanotube is occluded in the joining portion with the second nanotube.

According to the present invention, in order to achieve the above objects there is provided a field effect transistor wherein a first nanotube is arranged between a source electrode and a drain electrode, and the side of the first nanotube is joined with an end of an opening portion of a second nanotube that is a gate electrode.

According to the present invention, in order to achieve the above objects there is provided a method of manufacturing a nanotube with a T shaped structure by joining a second nanotube with a side of a first nanotube, wherein the method includes the steps of contacting the end of the opening portion of the second nanotube on the side of the first nanotube and joining the second nanotube with the side of the first nanotube.

According to the present invention, in order to achieve the above objects there is provided a method of manufacturing a field effect transistor wherein the method includes the steps of
arranging a first nanotube on a substrate,
joining one end of a second nanotube with the side of the first nanotube by contacting the end of the opening portion of the second nanotube on the side of the first nanotube, and
fixing firmly the ends of the first nanotube to source and drain electrodes by depositing a metallic film and fixing firmly the other side of the second nanotube to a terminal of a gate electrode.

According to the present invention, in order to achieve the above objects there is provided a method of manufacturing a field effect transistor wherein the method includes the steps of
forming a growth catalytic film for a nanotube at a plurality of portions on a substrate,
forming a first nanotube by vapor phase growth method using the growth catalytic film,
joining one end of a second nanotube with the side of the first nanotube by contacting the end of the opening portion of the second nanotube on the side of the first nanotube, and
fixing firmly the ends of the first nanotube to source and drain electrodes by depositing a metallic film and fixing firmly the other side of the second nanotube to a terminal of a gate electrode.

### EFFECT OF THE INVENTION

According to the nanotube with the T shaped structure of the present invention, the two nanotubes can be separated in the state of insulation, because the two nanotubes are arranged in the form of SP 3 bonding, in other words, the two nanotubes are joined with the diamond structure.

Accordingly, according to the present invention it is possible to control the electrical potential state of the first nanotube in accordance with a voltage applied to the second nanotube

Further, in the transistor of the present invention, both of the channel domain and the gate electrode for controlling thereof are made of nanotubes. Therefore, it is possible to provide the extremely fine transistor using miniaturization of the nanotube.

Further, in the nanotube constituting the channel, not only the semiconductor nanotube but also the metallic nanotube can be used in the channel domain, because the electronic state in the vicinity of the joining portion changes, and then a band gap is generated even in the metallic nanotube, thereby allowing control by the gate.

### BEST MODE OF CARRYING OUT THE INVENTION

Next, the embodiment of the present invention will be explained in detail referring to the drawings.

FIG. 1 is a flow chart showing one embodiment with regard to a method of manufacturing a nanotube with a T shaped structure of the present invention.

FIG. 2 illustrates side views corresponding to each step in series.

In the step S1, as shown in FIG. 2(a), a first nanotube 2 is formed on a substrate 1. In the other way, the first nanotube 2 formed preliminarily is arranged on the substrate 1.

As the substrate 1 crystal substrates such as silicon, quartz, sapphire, diamond and MgO, amorphous substrates such as alumina and glass, or a metallic substrate can be used.

In case of using the conductive substrate such as the metallic substrate, insulating coated layer is formed on the surface according to need.

The nanotube 2 is a single layered or multi layered carbon nanotube, or a single layered or multi layered boron nitride nanotube.

In case of growing the second nanotube 2 on the substrate 1, there is selectively formed on the substrate 1 a catalytic film, or a laminated film or a composite film made of catalyst carrier and catalyst which is a core for growth, and then there is formed a nanotube by vapor phase growth method such as thermal decomposition vapor phase growth (thermal CVD).

As the catalyst, there can be used the 3 A group metal such as Y and La, the 6 A group metal such as Mo, the 7 A group such as Mn, the 8 A group metal such as Fe, Co, Ni, Rh, Pd, and Pt, or one kind or a plurality of kinds of alloy including them or compound of them. As the catalyst carrier, there can be used the metal including the oxide, the oxide film or the hydroxylation film such as alumina and silica.

In order to selectively form patterns of those films, there can be used the selective ion irradiation technology.

In the substitution way, after forming films such as catalytic film thoroughly the patterning may be implemented using the photo lithography method and the etching technology.

Further, the patterning may be implemented by the liftoff technology. In case of making the nanotube by the thermal decomposition vapor phase growth, there can be used as the source gas the carbon compositions such as methane, ethane, ethylene, benzene, carbon monoxide, ethanol and methanol.

In case of B N nanotube, there can be used as the source, boron chloride (B Cl₃), and there can be used as the carrier gas, nitrogen+hydrogen. In the substitution way there can be used instead of thermal chemical vapor phase deposition method, other vapor phase growth method such as the laser ablation method.

In addition, in case of arranging a nanotube formed preliminarily as the nanotube 2 on the substrate 1, the nanotube is got out using a holding means such as probes of STM (scanning tunneling microscope) or AFM (atomic force microscope) and then is arranged by positioning on the substrate 1 while observing by TEM (transmission electron microscope)

The disinstallation of the holding means from the nanotube can be implemented by irradiating the electron beam onto the portion to be held of the nanotube. In advance of arranging the nanotube adhesive material may be coated preliminarily on the substrate 1.

In the next step S2, as shown in FIG. 2(b), the second nanotube 3 is got out using suitable holding means such as the probe of STM or the probe of AFM, and then the cap (fullerene portion formed at the top of the nanotube) of the second nanotube 3 is eliminated.

When the cap of the nanotube 3 is eliminated an opening end of the nanotube comes out to the surface which joins easily with impurity such as H (hydrogen) in the atmosphere, because carbon of the opening end is chemically activated due to dangling bond. Accordingly, it is preferable to maintain the level of vacuum in the chamber to the high vacuum of 1.33×10⁻⁵ Pa (10⁻⁷ Torr) or higher.

Also, it is preferable to operate in the high vacuum filled with inactive gas such as He, Ne, Ar and N₂ . The second nanotube 3 is a single layered or multi layered carbon nanotube or a single layered or multi layered B N (boron nitride) nanotube.

In the next step S3, as shown in FIG. 2(c), the opening portion of the second nanotube 3 is cleaned by eliminating impurity such as H which adheres to the top of the opening portion and joins with the activated carbon through irradiation of the electron beam.

In this cleaning it is preferable that the electron beam has an energy level to avoid sputtering of constituent elements of the nanotube. In the next step S4, as shown in FIG. 2(d), the end of the opening portion of the second nanotube 3 is contacted to the side of the first nanotube 2 operating the second nanotube 3 by the holding means while observing by TEM.

Then, the dangling bond at the end of the opening portion of the second nanotube 3 reacts with carbon of the first nanotube 2, and as the result, both of the nanotubes are joined in the form of SP³ bonding.

There is illustrated in FIG. 3 an atomic arrangement of the nanotube with thus formed T shaped structure. But, in FIG. 3 illustration of the first nanotube 2 is dropped out in the left half portion

The features of the T shaped structure according to the present invention are as follows;
(1) Both nanotubes are joined in the form of SP³ injunction.
(2) The first nanotube perfectly holds a tube like shape, in other words, no opening is formed in the joining portion.
(3) The joining portion is not formed in the shape of smooth and circular arc, that is, the second nanotube 3 rises in sharp from the first nanotube 2.

In the step S4 also, the joining may be implemented conducting the cleaning procedure by irradiating the electron beam to the end of the opening portion.

In case that in the step S2 the cap of the second nanotube picked by the holding means is already eliminated, the step S2 can be omitted. Further, in case that no contamination in the end of the opening portion is apparently conducted, the step S3 can be omitted. Also, in the above embodiment the electron beam is used to conduct the steps S2 and S3. However, instead ion of elements such as He, Ne, and Ar can be irradiated.

FIGS. 4(a) to 4(d) are side views in the order of steps showing the first embodiment of the method of manufacturing a transistor due to the present invention. In addition, the following drawings the nanotube in the hollow shape of the cylinder is drawn as the cylindrical column for simplification.

A silicon substrate 11, on which surface a silicon oxide film 12 is formed, is prepared. A first carbon nanotube (defined hereinafter as CNT) 13 is arranged thereon as referred to FIG. 4(a).

A good amount of adhesive material may be preliminarily coated on the silicon oxide film 12 prior to arrange the first CNT 13. The first CNT 13 may have the property as semiconductor or metal.

In the following embodiments the first CNT 13 is defined to have the same property.

FIG. 4(b) and subsequent drawings are different from FIG. 4(a) by 90 degrees in the direction of observation. A second CNT 14 is picked using a holding means 15 such as the probe of STM, and then a cap formed on the top of the second CNT 14 is eliminated by irradiating electron beam 14 as referred to FIG. 4(b).

It is preferable that the second CNT 14 is a metallic nanotube. However, the second CNT 14 may have the property as semiconductor.

In the following embodiments the second CNT 14 is defined to have the same property.

Consecutively, the end of the opening portion of the second CNT 14 is contacted to the side of the first CNT 13 operating the holding means 15 while irradiating electron beam 16 as referred to FIG. 4(c), and then both the nanotubes are joined as referred to FIG. 4(d)).

Thereafter, deposition of metallic film is implemented by selectively irradiating metallic ion to form a pair of source drain electrodes 17 at the end of the first CNT 13 and to form a gate terminal 18 at the end of the second CNT 14, and at the same time each end portion of each CNT is fixed on the silicon oxide film 12 as referred to FIG. 4(e).

FIG. 5 illustrates a plane view of the transistor thus formed.

FIGS. 6(a) to 6(f) are cross sectional views in the order of steps showing the second embodiment of the method of manufacturing a transistor due to the present invention.

FIGS. 7(a) to 7(c) are plane views in the order of steps showing the second embodiment.

A silicon substrate 21, on which surface a silicon oxide film 22 is formed, is prepared. And then a metallic film is deposited thereon to form a pair of source drain electrodes 27 and a gate terminal 28 using the photo lithography method and the dry etching method.

Through further depositing silicon oxide film, the source drain electrodes 27 and a gate terminal 28 are embedded in the silicon oxide film 22 by conducting polishing and planarization due to CMP (chemical mechanical polishing) as referred to FIG. 6(a) and FIG. 7(a).

Next, a catalytic layer 20 is formed on the one of the source drain electrodes 27 by selectively irradiating ions constituting one kind or plural kinds among metals such as Fe, Ni and Co as referred to FIG. 6(a).

As the method of forming the catalytic layer, a technique utilizing the deposition of metallic film due to sputtering method and the liftoff may be employed.

Then, the CNT is grown by the thermal decomposition vapor phase growth method wherein the catalytic layer 20 is defined as the start point. In the case, an electric field is applied in the direction between the source electrode and the drain electrode.

By this, the growing direction of the CNT is induced so as to direct from one source drain electrode to the other source drain electrode as referred to FIG. 6(c).

In case that the growing of the CNT is continued without change, the first CNT 23 is formed between a pair of source drain electrodes 27 as referred to FIG. 6(d), FIG. 7(b).

Next, the second CNT 24 is picked using the holding means 25. And then, after the cap is eliminated and the opening portion is cleaned using the electron beam when needed, the cleaned opening portion is contacted to the side of the first CNT 23, and then both the nanotubes are joined as referred to FIG. 6(e).

Thereafter, the other end of the second CNT 24 is positioned on the gate terminal 28 as referred to FIG. 6(f).

Here, FIG. 6(f) is different from FIGS. 6(a) to 6(e) by 90 degrees in the direction of observation.

Then, a fixed layer 29 for fixing the end portions of the CNT on the electrode and the terminal is formed selectively irradiating metallic ion.

Then, through removing the holding means 25 from the second CNT 24, the manufacturing steps of the transistor due to the second embodiment are completed as referred to FIG. 7(c).

FIGS. 8A(a) to 8B(f) are side views in the order of steps showing the third embodiment of the method of manufacturing a transistor due to the present invention. In addition, FIG. 8B(g) is a plane view of the transistor made by the third embodiment.

A silicon substrate 31, on which surface a silicon oxide film 32 is formed, is prepared. Photo resist is spin coated thereon, and then electron beam exposure and development are implemented to form a resist film 39 having an opening at a catalytic layer forming portion as referred to FIG. 8A(a).

There are two portions as the catalytic layer forming portion, which are located at the inner side of the source electrode and the drain electrode on the line connecting the source electrode and the drain electrode to be formed.

Then, a catalytic layer 30 is formed on the whole surface as referred to FIG. 8A(b). The forming method of the catalytic layer 30 can be employed appropriately in the methods known in general. Namely, there can be used the method such as depositing the catalytic metal or the catalytic metal compound due to vapor phase growth method, and coating solution including catalyst.

In addition, the catalyst carrier can be used together with catalyst. Also, the resist film 39 is removed using solution for peeling and then the catalytic layer 30 with the desired pattern remains on the substrate as referred to FIG. 8A(c).

Next, the CNT is grown by the thermal decomposition vapor phase growth method wherein two catalytic layers 30 are defined as the start point. In the case, an electric field is applied in the direction between the source electrode and the drain electrode. The direction of the electric field is inverted. By this, the CNT grows in the direction of the source drain electrodes to be formed as the starting point of the catalytic layer 30, as referred to FIG. 8A(d).

In case that the growing of the CNT is continued without change, the two CNT combine into one, and a first CNT 33is formed on the silicon oxide film 32 as referred to FIG. 8B(e).

Next, the second CNT 34 is picked using the holding means (not shown). And then, after the cap is eliminated and the opening portion is cleaned using the electron beam when needed, the cleaned opening portion is contacted to the side of the first CNT 33, and then the side of the first CNT 33 is joined with the opening portion of the second CNT 34.

Thereafter, the other end of the second CNT 34 is positioned on the gate terminal to be formed, as referred to FIG. 8B(f). Here, FIG. 8B(f) is different from FIGS. 8B(a) to 8B(e) by 90 degrees in the direction of observation.

Then, source drain electrodes 37 are formed at the two end portions of the first CNT 33 by selectively irradiating metallic ion. Then a gate terminal 38 is formed at one end of the second CNT 34, and then the end portion of the CNT is fixed on a silicon oxide film 32. Then, through removing the holding means from the second CNT 34, the transistor due to the second embodiment is made as shown in FIG. 8B(g).

In the above embodiments, it is preferable that the first and the second CNT are single layered nanotubes, and also the CNT may be multi layered nanotube. Further, it is possible to use the BN nanotube as the nanotube for the gate electrode.

### EXAMPLE 1

Al is deposited using sputtering method on a silicon substrate on which surface a silicon oxide film is formed, and then a source electrode and a drain electrode are formed by patterning due to the electron beam lithography technique.

A catalytic layer made of Ni is formed on the source electrode and the drain electrode by selectively irradiating the ion beam.

A first single layered CNT is formed between the source electrode and the drain electrode by growing the CNT due to the thermal CVD method.

As a second CNT, a preliminarily formed single layered CNT is picked at the top of the probe of the STM using intense electric field.

The end of the opening of the second CNT is approached to the first CNT while observing by the TEM, because no cap is confirmed at the top of the second CNT.

And the second CNT is contacted to the first CNT, while removing impurity which is assumed to be absorbed to the end of the opening of the second CNT by irradiating the electron beam accelerated at 300 kV, then there is formed a T letter shaped junction joined between both the CNT.

Consecutively, after a gate terminal is formed at the end portion of the second CNT by selectively irradiating metallic ion beam, the probe of the STM is removed from the second CNT.

Next, voltage characteristic of the gate is examined when voltage of 1 volt is applied between the source drain electrodes, and then it follows that the mutual conductance is about 6000 μS/μm.

This result represents to be equivalent to the conventional type of nanotube transistor which forms the gate electrode on the insulating film.

On the other hand, the nanotube transistor according to the present invention is capable of high speed operation compared with the conventional transistor, and then, 10 T Hz or more in the cutoff frequency can be respected, because length of the channel using CNT as the gate electrode is in the order of nanometer.

In addition, in case that the gate voltages exceeds 1 volt, no characteristic of transistor is confirmed, because of the current leakage.

### AVAILABILITY ON INDUSTRY

The nanotube with T shaped structure according to the present invention is constituted such that two nanotubes are joined in the form of SP³ bonding. Accordingly, there is no electric conductivity between the two nanotubes, and then it is possible that in accordance with voltages applied to the one nanotube, electronic state of the other nanotube can be controlled.

The nanotube with T shaped structure according to the present invention is can be utilized not only as the field effect transistor with insulating gate, but also as the cold cathode with control gate and the superconducting device capable of controlling super conduction/normal conduction by the gate. Also, the nanotube with T shaped structure can be applied to the capacitor or the baricap by utilizing insulator of the joining portion as a dielectric film.

### BRIEF DESCRIPTION OF THE DRAWING

FIG. 1 is a flow chart showing one embodiment with regard to a method of manufacturing a nanotube with a T shaped structure of the present invention.

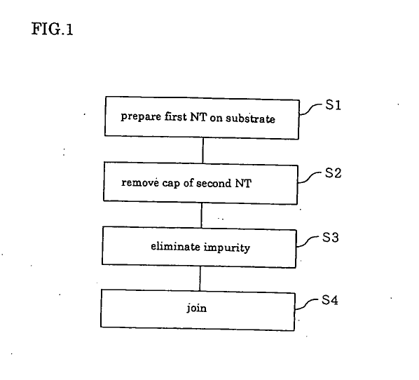

FIG. 2 illustrates side views corresponding to each step in series in one embodiment with regard to a method of manufacturing a nanotube with a T shaped structure of the present invention.

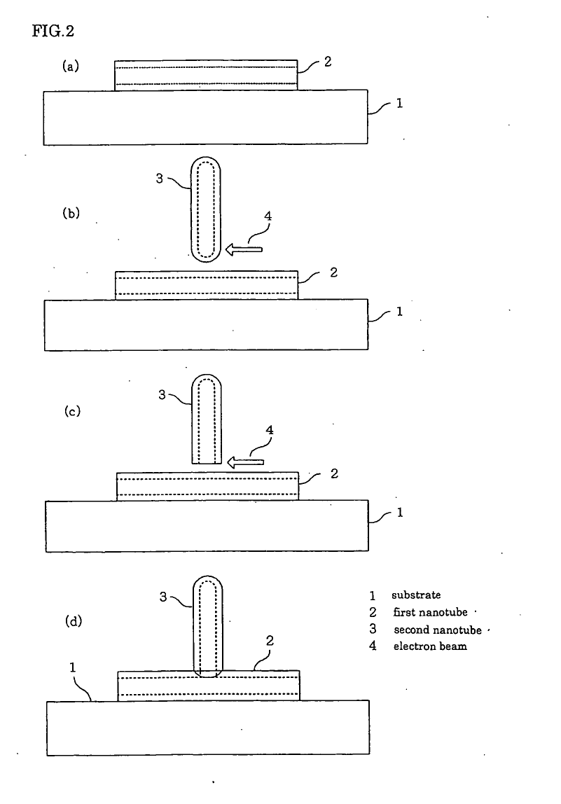

FIG. 3 illustrates a structure of a nanotube with a T shaped structure of the present invention.

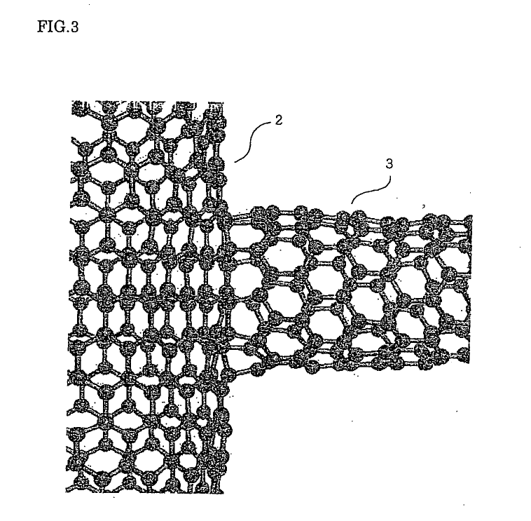

FIG. 4 illustrates side views in the order of steps showing a first embodiment of a method of manufacturing a transistor due to the present invention.

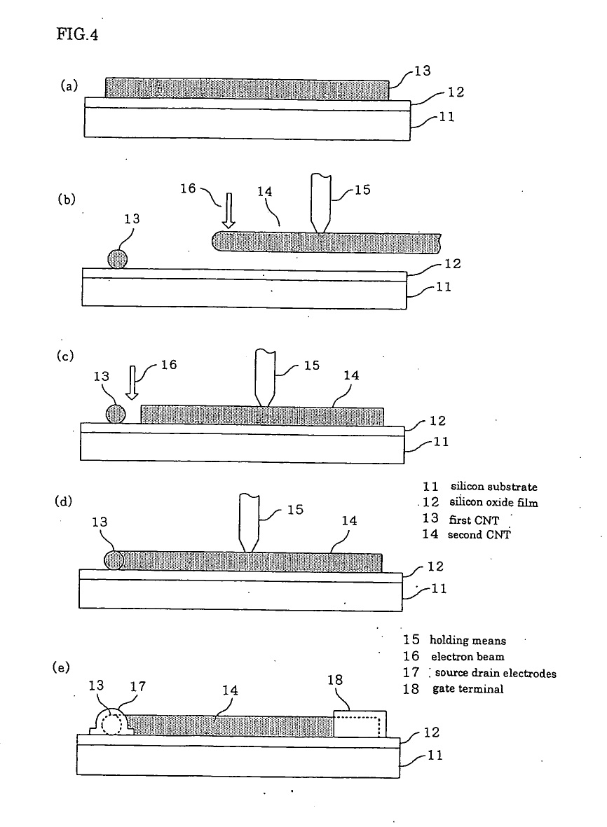

FIG. 5 is a plane view of a transistor formed by a manufacturing method with regard to a first embodiment of the present invention.

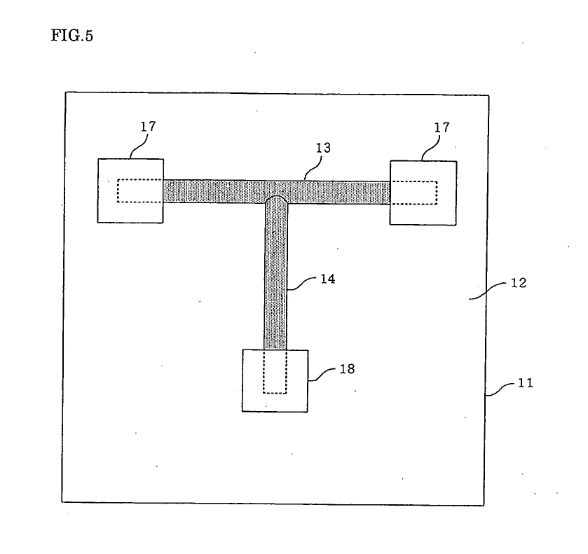

FIG. 6 illustrates cross sectional views in the order of steps showing a second embodiment of a method of manufacturing a transistor due to the present invention.

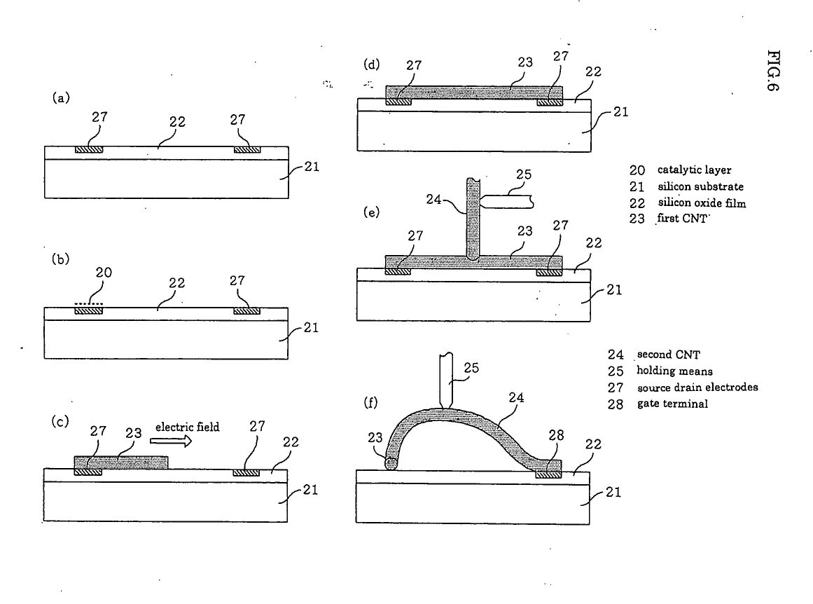

FIG. 7 illustrates plane views in the order of steps showing a second embodiment of a method of manufacturing a transistor due to the present invention.

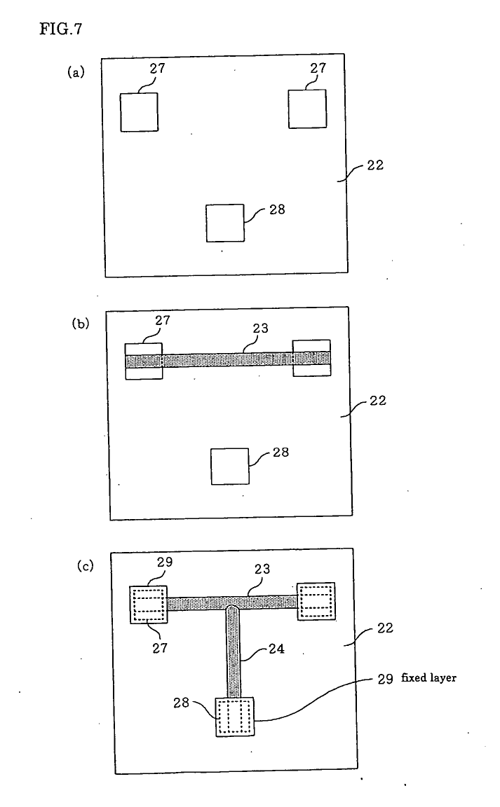

FIG. 8A illustrates cross sectional views in the order of steps showing a third embodiment of a method of manufacturing a transistor due to the present invention.(part 1)

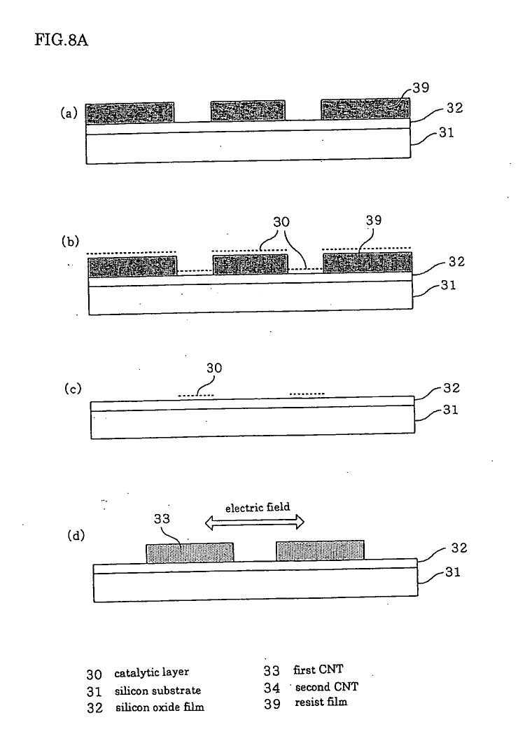

FIG. 8B illustrates cross sectional views in the order of steps showing a third embodiment of a method of manufacturing a transistor due to the present invention.(part 2)

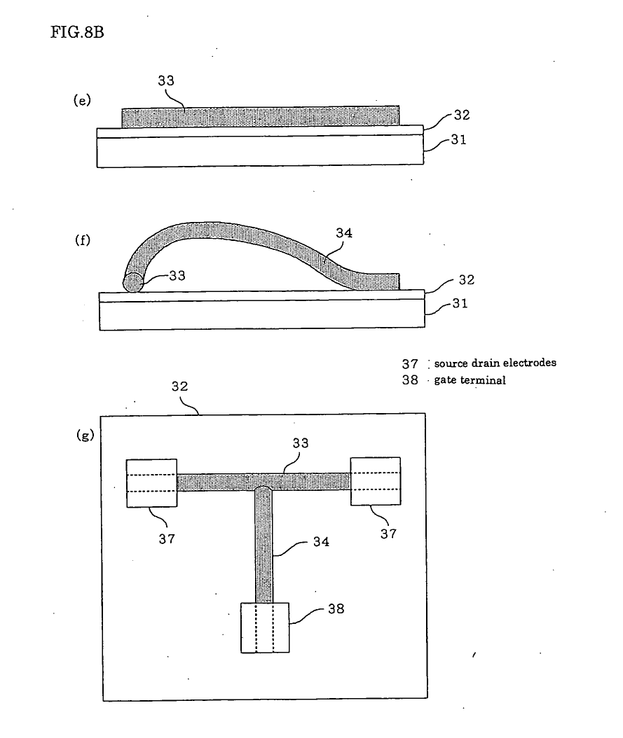

1. A nanotube with a T shaped structure wherein a side of a first nanotube and an end of an opening portion of a second nanotube are arranged in the form of SP 3 bonding.

2. A nanotube with a T shaped structure in which an end of an opening portion of a second nanotube joins with a side of a first nanotube wherein the first nanotube is occluded in the joining portion with the second nanotube.

3. A field effect transistor wherein a first nanotube is arranged between a source electrode and a drain electrode, and the side of the first nanotube is joined with an end of an opening portion of a second nanotube that is a gate electrode.

4. A field effect transistor according to claim 3 wherein the first nanotube and the second nanotube are arranged in the form of SP 3 bonding.

5. A field effect transistor according to claim 3 wherein the second nanotube has a metallic property.

6. A field effect transistor according to claim 3 wherein the first nanotube comprises a carbon nanotube.

7. A field effect transistor according to claim 3 wherein the first nanotube comprises a single layered nanotube.

8. A field effect transistor according to claim 3 wherein the second nanotube comprises either of a carbon nanotube or a boron nitride nanotube.

9. A method of manufacturing a nanotube with a T shaped structure by joining a second nanotube with a side of a first nanotube, wherein the method includes the steps of contacting the end of the opening portion of the second nanotube on the side of the first nanotube and joining the second nanotube with the side of the first nanotube.

10. A method of manufacturing a nanotube with a T shaped structure according to claim 9, wherein cleaning treatment is implemented at the end of the opening portion of the second nanotube when it is joined.

11. A method of manufacturing a nanotube with a T shaped structure according to claim 9, wherein the joining step is implemented in the high vacuum of 1.33×10⁻⁵ Pa(10⁻⁷ Torr) or higher.

12. A method of manufacturing a nanotube with a T shaped structure according to claim 9, wherein the joining step is implemented in the atmosphere of noble gas or nitrogen.

13. A method of manufacturing a field effect transistor wherein the method includes the steps of;
arranging a first nanotube on a substrate,
joining one end of a second nanotube with the side of the first nanotube by contacting the end of the opening portion of the second nanotube on the side of the first nanotube, and
fixing firmly the ends of the first nanotube to source and drain electrodes by depositing a metallic film and fixing firmly the other side of the second nanotube to a terminal of a gate electrode.

14. A method of manufacturing a field effect transistor wherein the method includes the steps of
forming a growth catalytic film for a nanotube at a plurality of portions on a substrate,
forming a first nanotube by vapor phase growth method using the growth catalytic film,
joining one end of a second nanotube with the side of the first nanotube by contacting the end of the opening portion of the second nanotube on the side of the first nanotube, and
fixing firmly the ends of the first nanotube to source and drain electrodes by depositing a metallic film and fixing firmly the other side of the second nanotube to a terminal of a gate electrode.

15. A field effect transistor according to claim 4 wherein the second nanotube has a metallic property.

16. A field effect transistor according to claim 4 wherein the first nanotube comprises a carbon nanotube.

17. A field effect transistor according to claim 5 wherein the first nanotube comprises a carbon nanotube.

18. A field effect transistor according to claim 4 wherein the first nanotube comprises a single layered nanotube.

19. A field effect transistor according to claim 5 wherein the first nanotube comprises a single layered nanotube.

20. A field effect transistor according to claim 6 wherein the first nanotube comprises a single layered nanotube.

21. A field effect transistor according to claim 4 wherein the second nanotube comprises either of a carbon nanotube or a boron nitride nanotube.

22. A field effect transistor according to claim 5 wherein the second nanotube comprises either of a carbon nanotube or a boron nitride nanotube.

23. A field effect transistor according to claim 6 wherein the second nanotube comprises either of a carbon nanotube or a boron nitride nanotube.

24. A field effect transistor according to claim 7 wherein the second nanotube comprises either of a carbon nanotube or a boron nitride nanotube.

25. A method of manufacturing a nanotube with a T shaped structure according to claim 10, wherein the joining step is implemented in the high vacuum of 1.33×10⁻⁵ Pa(10⁻⁷ Torr) or higher.

26. A method of manufacturing a nanotube with a T shaped structure according to claim 10, wherein the joining step is implemented in the atmosphere of noble gas or nitrogen.

27. A method of manufacturing a nanotube with a T shaped structure according to claim 11, wherein the joining step is implemented in the atmosphere of noble gas or nitrogen.
